(19) United States
(12) Patent Application Publication
(10) Pub. No.: US 2006/0226880 A1
(43) Pub. Date: Oct. 12, 2006

(54) Internal power supply control method, internal power supply circuit, and semiconductor device

(75) Inventors: Takeshi Akiyama, Tokyo (JP); Yusuke Shimizu, Tokyo (JP); Yoji Idei, Tokyo (JP)

Correspondence Address: FOLEY AND LARDNER LLP;SUITE 500, 3000 K STREET NW, WASHINGTON, DC, 20007, US

(73) Assignee: Elpida Memory, Inc.

(21) Appl. No.: 11/388,206

(22) Filed: Mar. 24, 2006

(30) Foreign Application Priority Data
Mar. 25, 2005 (JP) 2005-88465

(51) Int. Cl. H03B 19/00

(52) U.S. Cl. 327/113

(57) ABSTRACT

When a DLL circuit using a clock is employed, the internal power supply circuit is arranged between the external power supply and the DLL circuit. The internal power supply circuit supplies power from the external power supply after reducing the voltage thereof. The internal power supply circuit is divided into a basic power supply circuit and an additional power supply circuit. The internal power supply circuit further includes a frequency determination circuit, which samples the clock to detect the frequency thereof, and generates a determination signal based on the detected frequency. Based on the determination signal, the internal power supply circuit controls the connection or disconnection of the additional power supply circuit. The basic power supply circuit and the additional power supply circuit are activated in a high frequency range, whereas only the basic power supply circuit is activated in a low frequency range.

This application claims priority to prior Japanese patent application JP 2005-88465, the disclosure of which is incorporated herein by reference.

### BACKGROUND OF THE INVENTION

This invention relates to an internal power supply control method, an internal power supply circuit employing this control method, and a semiconductor device including such an internal power supply circuit.

In recent years, there have been developed microprocessors operable at higher speeds and yet with lower power consumption. This trend is increasing the demand for chips having a higher data transferring speed and yet low power consumption. In response to such demand of the users, chips are now being developed which are capable of carrying out high speed operation and yet can suppress the power consumption. It is particularly essential to reduce the current consumption of delay locked loop (DLL) circuits operating at high speeds. As is well known, the power consumption is increased as the clock frequency becomes higher. DLL circuits are mass-produced to minimize production cost, while they are designed on the basis of a maximum possible frequency so as to be applicable to a variety of apparatuses. However, the DLL circuits are sometimes used at a frequency substantially lower than the designed frequency, depending on semiconductor devices in which they are used.

In view of the circumstances associated with the increase of clock speed, some of the existing DLL circuits are provided with a plurality of small-sized and small-capacity power supply circuits as an internal power supply suitable for mass production. Specifically, a DLL circuit is provided with a plurality of small power supply circuits each having a certain current supply capability. When the DLL circuit, which is provided with a plurality of small power supply circuits, operates with low-speed clocks, the current consumption is low and hence some of the small power supply circuits are not required to operate.

With reference to FIGS. 1 to 4, description will be made on an internal power supply circuit 100 and its peripheral circuits actually used in a semiconductor device including this type of DLL circuit 2.

The internal power supply circuit 100 shown in the diagrams has two small power supply circuits 111 and 112. The internal power supply circuit 100 receives an external power supply voltage V_{DD} from a current supply 3 through a wiring and outputs an internal power supply voltage V_{PERI} that has been reduced to be supplied to the DLL circuit 2. FIG. 1 shows a circuit configuration used for the DLL circuit 2 operating with low-speed clocks. Therefore, the wiring 110 connecting to the small power supply circuit 112 is disconnected. Consequently, the external power supply voltage V_{DD} is supplied to only one of the small power supply circuits, namely, the small power supply circuit 111, and not to the small power supply circuit 112.

As shown in FIG. 2, the configuration shown in FIG. 1 is only effective for low clock frequencies, and not effective for high clock frequencies. However, the circuit configuration of FIG. 1 consumes low current since no current is supplied to the small power supply circuit 112.

FIG. 3 shows a circuit configuration used for the DLL circuit operating with high-speed clocks. In this configuration, the two small power supply circuits 111 and 112 are connected to the DLL circuit 2 by a wiring, for example an aluminum wiring 110. Consequently, the DLL circuit 2 is supplied with current from both the small power supply circuits 111 and 112. This circuit configuration is therefore effective for operation with high-speed clocks as shown in FIG. 4. However, if this circuit configuration is used for operation with low-speed clocks, the supply capability will exceed the capability actually required, resulting in consumption of unnecessary current.

As described above, it is necessary to disconnect or connect the wiring 110 connecting to the small power supply circuits 111 and 112 of the internal power supply circuit 100 in order to render the circuit configuration effective for operation with high-speed clocks or low-speed clocks. Using these circuit configurations, however, the user is required to switch connection of the internal power supply formed on a chip depending upon the user's desired operation, either with high-speed clocks or with low-speed clocks. Such switching is not possible or can not be carried out by the user.

More specifically, as shown in FIGS. 1 and 3, the internal power supply circuit for the DLL circuit is divided into a plurality of circuits to make it possible to supply an appropriate amount of power to the DLL circuit. Thereby, the adjustment of the current consumption has to be carried out by connection or disconnection of the aluminum wiring. Consequently, the user is required to select an appropriate internal power supply, but this is difficult or impossible for the user.

### SUMMARY OF THE INVENTION

It is therefore an object of the present invention to provide an internal power supply control method which does not require modification of the layout for supplying an appropriate amount of power to a DLL circuit.

The present invention provides an internal power supply control method for controlling the supply of current to an electronic circuit to minimize the useless current consumption. The present invention also provides an internal power supply circuit employing this control method, and a semiconductor device having this internal power supply circuit. The electronic circuit has characteristics that the current consumption thereof substantially varies depending on the frequency of an externally-input clock. Accordingly, the current supplied thereto is controlled by detecting the frequency of the externally-input clock provided to the electronic circuit. The present invention particularly provides a semiconductor storage device designed to synchronize the phase of data input to a high speed memory such as a dynamic random access memory (DRAM) with the phase of an internal clock.

According to the present invention, the user is allowed to use an internal power supply circuit formed on a chip without concerning about whether the clock to be used is a high-speed clock or low-speed clock. The present invention has the following main characteristics. An internal power supply circuit is divided into a plurality of small power supply circuits, and these small power supply circuits are arranged in parallel between an external power supply and an electronic circuit operating with a clock, such as a DLL circuit. The internal power supply circuit further includes a frequency determination circuit. The frequency determination circuit samples the clock to detect the frequency thereof and, based on the detected frequency, controls the connection between each of the small power supply circuits and the electronic circuit such as a DLL circuit.

Specifically, if the detected frequency is higher than a predetermined frequency, all the small power supply circuits are activated. In contrast, if the detected frequency is lower than the predetermined frequency, some of the small power supply circuits are completely inactivated for totally stopping the consumption of current. According to the present invention, the number of the small power supply circuits to be activated can be controlled by the frequency determination.

The small power supply circuits desirably include one basic power supply circuit for normally connecting the external power supply and the electronic circuit, and at least one or more additional power supply circuits which are connected or disconnected conditionally on the basis of the frequency to be used. Further, at least the additional power supply circuits of the plurality of small power supply circuits preferably have an identical current supply capability. The control can be simplified by this.

The small power supply control according to the present invention controls an internal power supply circuit which supplies power to an electronic circuit having characteristics that the current consumption thereof substantially varies depending on the frequency of an externally-input clock. Therefore, the internal power supply circuit is divided into a plurality of small power supply circuits. The internal power supply circuit detects a frequency of a clock to be supplied to the electronic circuit, and controls the connection of the plurality of small power supply circuits according to the detected clock frequency. The provision of the internal power supply circuit according to the present invention makes it possible to automatically adjust the number of small power supply circuits to be connected to the electronic circuit as required. The present invention thus has an advantageous effect that the user is not required anymore to do the wiring work depending upon whether the clock to be used is a high-speed clock or a low-speed clock for minimizing the current consumption.

### BRIEF DESCRIPTION OF THE DRAWINGS

FIG. 1 shows an example of a circuit configuration using a conventional power supply control method, in which a wiring is disconnected;

FIG. 2 is a graph illustrating an example of a relationship between clock frequency and circuit current in the circuit configuration of FIG. 1;

FIG. 3 shows an example of a circuit configuration in which a connection circuit is formed by connecting the wiring of FIG. 1;

FIG. 4 is a graph illustrating an example of a relationship between clock frequency and circuit current in the circuit configuration of FIG. 3;

FIG. 5 is a block diagram showing an embodiment of a circuit configuration using a power supply control method according to the present invention (first embodiment);

FIG. 6 is a graph illustrating an example of a relationship between clock frequency and circuit current in the circuit configuration of FIG. 5 (first embodiment);

FIG. 7 is a block diagram showing an embodiment of a circuit configuration of the frequency determination circuit of FIG. 5 (first embodiment);

FIG. 8 is a time chart for explaining the determination by detection of a frequency during operation with high-speed clocks of the frequency determination circuit of FIG. 7 (first embodiment);

FIG. 9 is a time chart for explaining the determination by detection of a frequency during operation with low-speed clocks of the frequency determination circuit of FIG. 7 (first embodiment);

FIG. 10 is an explanatory diagram illustrating another embodiment of a circuit configuration of the frequency determination circuit of FIG. 5 in which a plurality of additional power supply circuits are provided (second embodiment);

FIG. 11 is a block diagram showing an embodiment of a circuit configuration applicable to the frequency determination circuit of FIG. 10 (second embodiment);

FIG. 12 is a graph illustrating an example of a relationship between clock frequency and circuit current when N is three in FIG. 10 (second embodiment); and

FIG. 13 is a time chart for explaining the determination when the frequency determination circuit of FIG. 11 detects a frequency based on an example of a clock frequency when N is three (second embodiment).

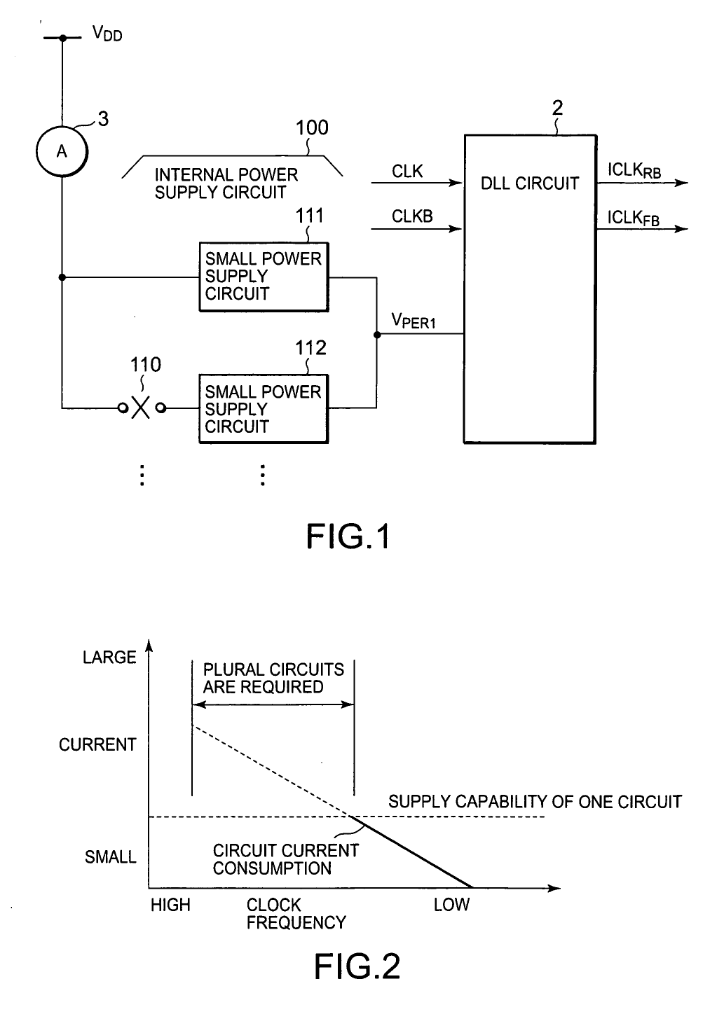

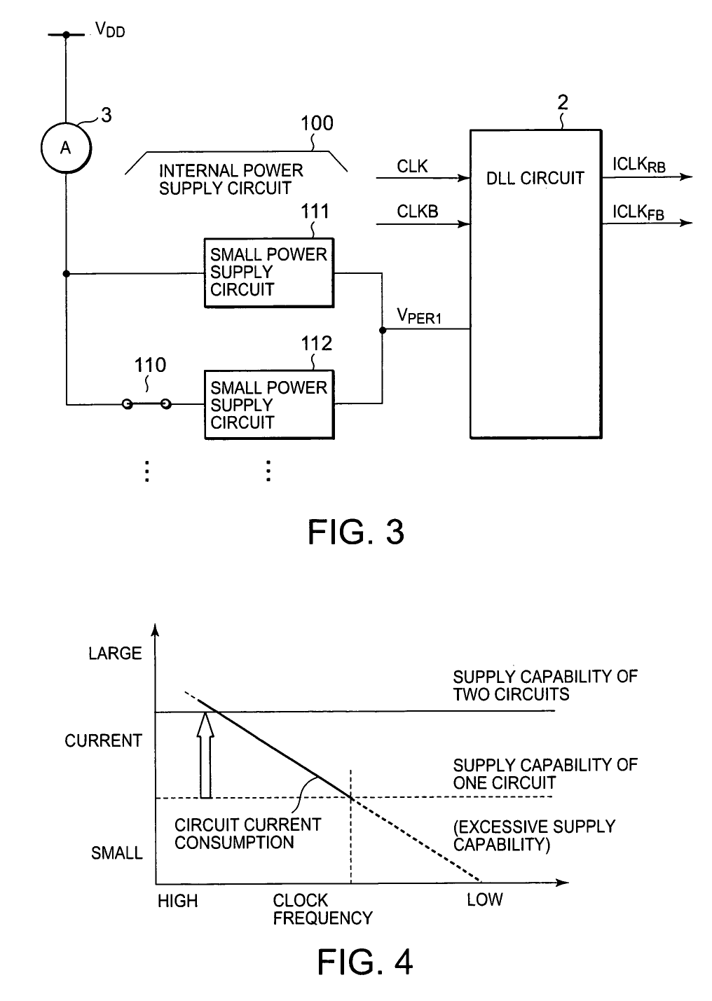

### DESCRIPTION OF THE PREFERRED EMBODIMENTS

The present invention will be described more particularly with reference to the accompanying drawings.

The present invention relates to the provision of an internal power supply circuit for supplying externally-supplied power to an electronic circuit using a clock. An object of the present invention is to eliminate the need of wiring works which have conventionally been required for the provision of an internal power supply circuit to adjust the clock speed to a high or low speed according to each user's need. For achieving this object, the present invention divides an internal power supply circuit into a plurality of small power supply circuits. The internal power supply circuit samples a clock to detect the frequency of the clock, and controls the connection and disconnection between each of the small power supply circuits and the electronic circuit based on the detected frequency.

At least one of the plurality of small power supply circuits is a basic power supply circuit that is normally connected. At least one of other circuits is an additional power supply circuit that is connected conditionally on the basis of the frequency to be employed. It is particularly desirable for the control of connection that the basic power supply circuit is only one. The internal power supply circuit has a frequency determination circuit. The frequency determination circuit samples a clock to detect the frequency thereof, and controls the connection of the additional power supply circuit based on the detected frequency. As a result, an appropriate number of small power supply circuits corresponding to the clock frequency to be employed by the electronic circuit are connected in parallel between the external power supply and the electronic circuit.

### First Embodiment

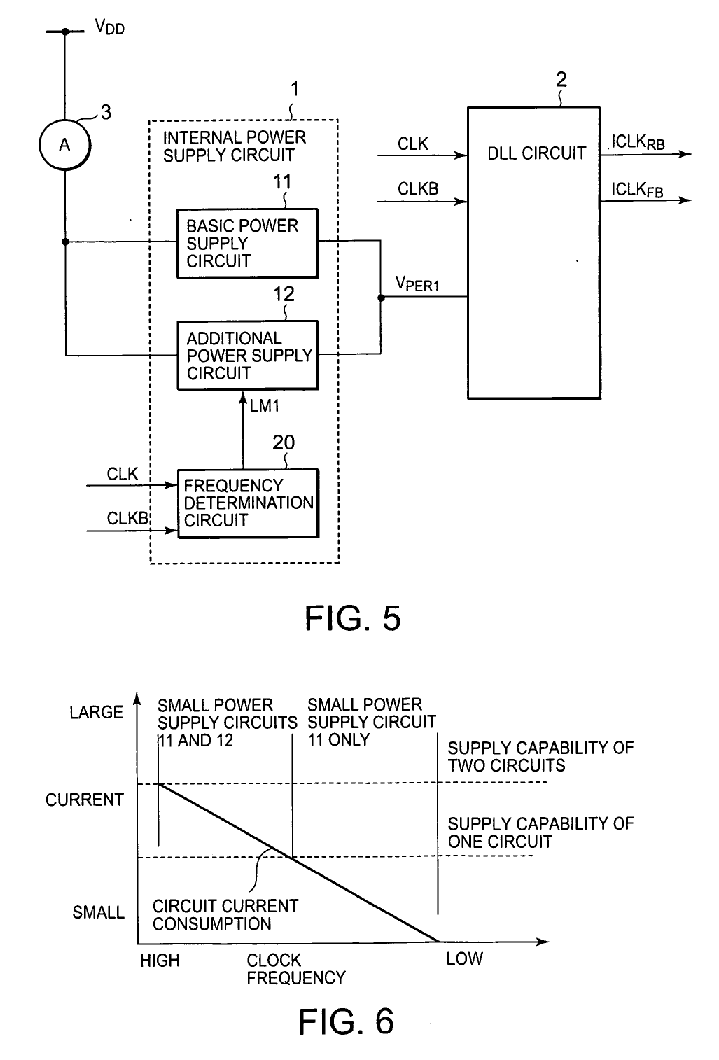

A first embodiment of the present invention will be described with reference to FIGS. 5 and 6 together.

FIG. 5 shows, as a first embodiment of the present invention, a configuration of a functional block including an internal power supply circuit 1 and peripheral circuits thereof. The configuration shown in FIG. 5 includes the internal power supply circuit 1, a delay locked loop (DLL) circuit 2, and an external current source A3. The external current source A3 is a circuit which receives an external power supply voltage V_{DD} and supplies current to the internal power supply circuit 1.

The internal power supply circuit 1 is composed of a basic power supply circuit 11, an additional power supply circuit 12, and a frequency determination circuit 20. The internal power supply circuit 1 is arranged between the DLL circuit 2 and the external current source A3 having an external power supply voltage V_{DD}. Receiving the external power supply voltage V_{DD}, the internal power supply circuit 1 reduces the same to an internal power supply voltage V_{PERI} and supplies the internal power supply voltage V_{PERI} to the DLL circuit 2.

The DLL circuit 2 is one of typical circuits having characteristics that the current consumption substantially varies depending on the frequency of an externally-input clock. The DLL circuit 2 operates while receiving the internal power supply voltage V_{PERI} and clocks CLK and CLKB.

The basic power supply circuit 11 of the internal power supply circuit 1 is a small power supply circuit and supplies substantially a half of a maximum amount of current consumed by the DLL circuit 2 operating in a high frequency state. When a semiconductor storage device for example is in a low frequency state such as a standby/active state, the basic power supply circuit 11 supplies a small amount of current suitable for such state.

The additional power supply circuit 12 is also a small power supply circuit and operates in parallel and in combination with the basic power supply circuit 11 to supply a sufficient amount of current to satisfy the maximum amount current consumed by the DLL circuit 2 operating in the high frequency state. On the other hand, the additional power supply circuit 12 includes a switching means and is controlled by the frequency determination circuit 20 to stop the supply of power and cut off the output.

The frequency determination circuit 20 receives the same clocks CLK and CLKB as those input to the DLL circuit 2. The frequency determination circuit 20 detects and determines the frequency of the clocks, and notifies the clock frequency to the additional power supply circuit 12.

FIG. 6 is a diagram showing characteristics for explaining the operating states of the basic power supply circuit 11 and the additional power supply circuit 12 in FIG. 5. FIG. 6 shows a relationship between a clock frequency and current supplied to the DLL circuit 2.

More specifically, the additional power supply circuit 12 is added to increase the capability of supplying power to the DLL circuit 2 according to the increase of the clock speed. However, this will entail useless consumption of power when the DLL circuit 2 operates with low-speed clocks. In order to prevent such useless power consumption, if the frequency determination circuit 20 determines that the received clocks CLK and CLKB are low-speed clocks, the frequency determination circuit 20 transmits a determination signal LM1 to the additional power supply circuit 12 to instruct the additional power supply circuit 12 to cut off the power output.

In this manner, the frequency determination circuit 20 determines whether the received clocks CLK and CLKB are low-speed clocks or high-speed clocks and transmits the determination signal LM1 to the additional power supply circuit 12. On the other hand, receiving the determination signal LM1, the additional power supply circuit 12 determines whether or not power is to be supplied from the additional power supply circuit 12. This means that the internal power supply circuit 1 supplies current to the DLL circuit 2 with a supply capability corresponding to two small power supply circuits when the additional power supply circuit 12 is activated, whereas supplies current to the DLL circuit 2 with a supply capability corresponding to one small power supply circuit when the additional power supply circuit 12 is inactivated. As a result, connection or disconnection of the wiring in the internal power supply circuit is not required to be set by the user nor by the manufacturer before delivery. Therefore, unlike the conventional technique, the present invention is able to avoid the useless consumption of power during low-speed operation.

Description will now be made of the frequency determination circuit 20 outputting the determination signal LM1 according to the first embodiment of the present invention, with reference to FIG. 5 and FIGS. 7 to 9.

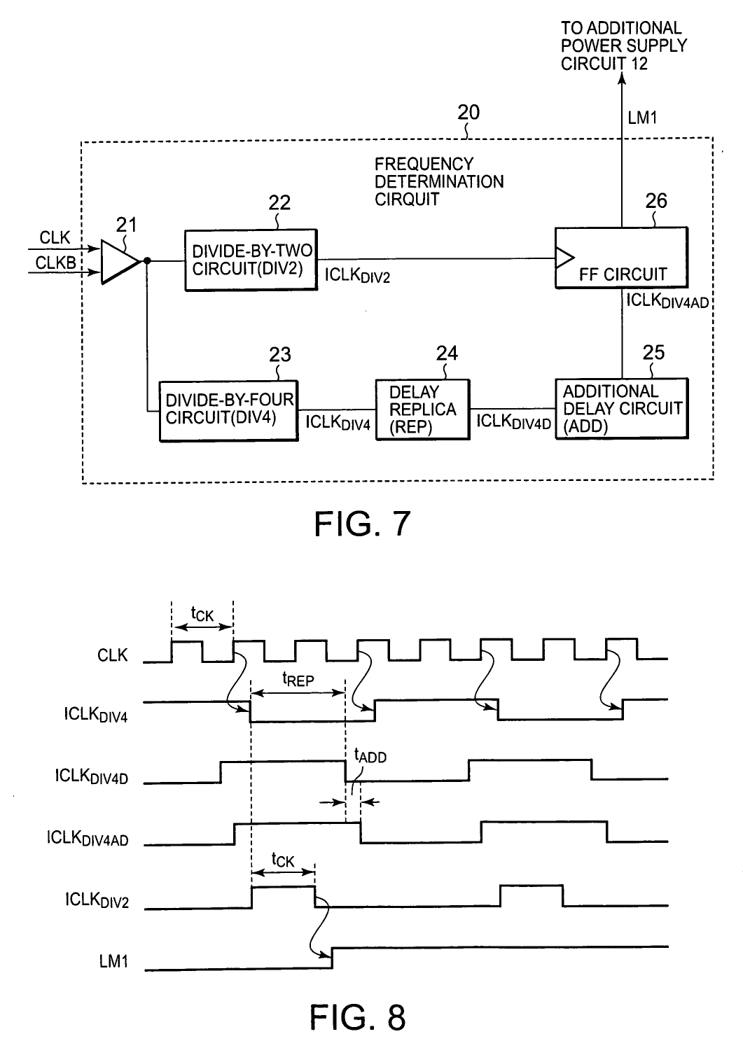

FIG. 7 is a diagram illustrating a configuration of the circuit block of the frequency determination circuit 20 in FIG. 5.

As shown in FIG. 7, the frequency determination circuit 20 includes a clock buffer 21, a divide-by-two circuit (DIV2) 22, a divide-by-four circuit (DIV4) 23, a delay replica (REP) 24, an additional delay circuit (ADD) 25, and a flip-flop (FF) circuit 26.

The clock buffer 21 receives an external clock signal CLK and outputs the same to the divide-by-two circuit 22 and the divide-by-four circuit 23. Receiving the output from the clock buffer 21, the divide-by-two circuit 22 produces a clock signal ICLK_{DIV2} having a twice clock period and outputs the same to the FF circuit 26. Receiving the output from the clock buffer 21, the divide-by-four circuit 23 produces a clock signal ICLK_{DIV4} having a four-times clock period and outputs the same to the delay replica 24. Receiving the output signal ICLK_{DIV4} from the divide-by-four circuit 23, the delay replica 24 delays the output signal ICLK_{DIV4} by a predetermined time t_{REP}, and outputs the delayed signal to the additional delay circuit 25 as a signal ICLK_{DIV4D}. Receiving the output signal ICLK_{DIV4D} from the delay replica 24, the additional delay circuit 25 delays the same by time t_{ADD} and outputs the delayed signal ICLK_{DIV4AD} to the FF circuit 26. Upon receiving the clock signal ICLK_{DIV2} from the divide-by-two circuit 22, the FF circuit 26 generates a determination signal LM1 set to “on” if the signal ICLK_{DIV4AD} received from the additional delay circuit 25 is “ion”, and sends the determination signal LM1 to the additional power supply circuit 12.

Upon receiving the determination signal LM1 set to “on”, the additional power supply circuit 12 supplies current to the DLL circuit 2. The generation of the determination signal LM1 set to “on” or “off” will be described below with reference to the drawings.

Description will firstly be made on the power supply capability that is required for high-speed operation, with reference to FIGS. 7 and 8 together. FIG. 8 is a timing chart when a period t_{CK} of the external clock signal CLK is fast and relatively short and thus the additional power supply circuit 12 is activated in addition to the basic power supply circuit 11.

An output signal ICLK_{DIV4} from the divide-by-four circuit 23 becomes a signal ICLK_{DIV4D} after being delayed by time t_{REP} by the delay replica 24. This signal ICLK_{DIV4D} is received by the additional delay circuit 25 which delays the signal by time t_{ADD} to generate a signal ICLK_{DIV4AD}. The signal ICLK_{DIV4AD} is input to the data input terminal of the FF circuit 26. When the FF circuit 26 samples the signal ICLK_{DIV4AD} at the rising edge of an output signal ICLK_{DIV2} from the divide-by-two circuit 22, the following expression (1) is obtained
t_{CK}<t_{REP}+t_{ADD} (1)

Under this condition, the determination signal LM1 becomes high (H) level, whereby the signal to turn on the circuit operation is sent to the additional power supply circuit 12 (FIG. 5). Consequently, the DLL circuit 2 can be supplied with the power supply capability corresponding to two supply circuits that is required for the high-speed operation.

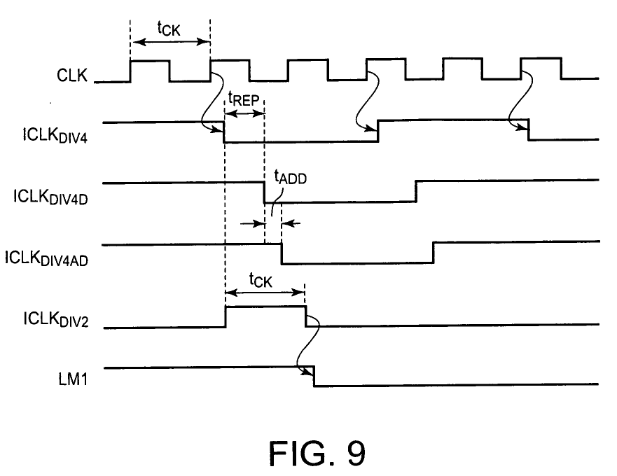

A description will now be made of the power supply capability that is required for low-speed operation, with reference to FIGS. 7 and 9 together. FIG. 9 is a timing chart when the period t_{CK} of the external clock signal CLK is slow and relatively long and thus the power supply from the additional power supply circuit 12 (FIG. 5) is cut off.

In this case, as seen from FIG. 9, the following expression (2) is obtained:
t_{CK}>t_{REP}+t_{ADD} (2)

Specifically, when the FF circuit 26 samples the output signal ICLK_{DIV4AD} from the additional delay circuit 25 at the rising edge of the output signal ICLK_{DIV2} from the divide-by-two circuit 22, the determination signal LM1 output by the FF circuit 26 becomes low (L) level. Accordingly, the signal to turn off the circuit operation is sent to the additional power supply circuit 12. The DLL circuit thus can be supplied with minimum required power supply capability for low-speed operation.

The clock period t_{CK} to determine whether the additional power supply circuit 12 is to be used or not is represented by the following equation (3):
t_{CK}=t_{REP}+t_{ADD} (3)

On the other hand, the limit not to use the additional power supply circuit 12 is defined by the following equation (4):
t_{CK}=t_{REP} (4)

Accordingly, the frequency determination circuit 20 sets a margin of the additional delay time t_{ADD} with respect to the equation (4). This is for the purpose of avoiding the malfunction condition as represented by the following expression (5) even if the time t_{REP} is varied by fluctuation in the power supply voltage or temperature after the determination of the frequency.
t_{CK}<t_{REP} (5)

### Second Embodiment

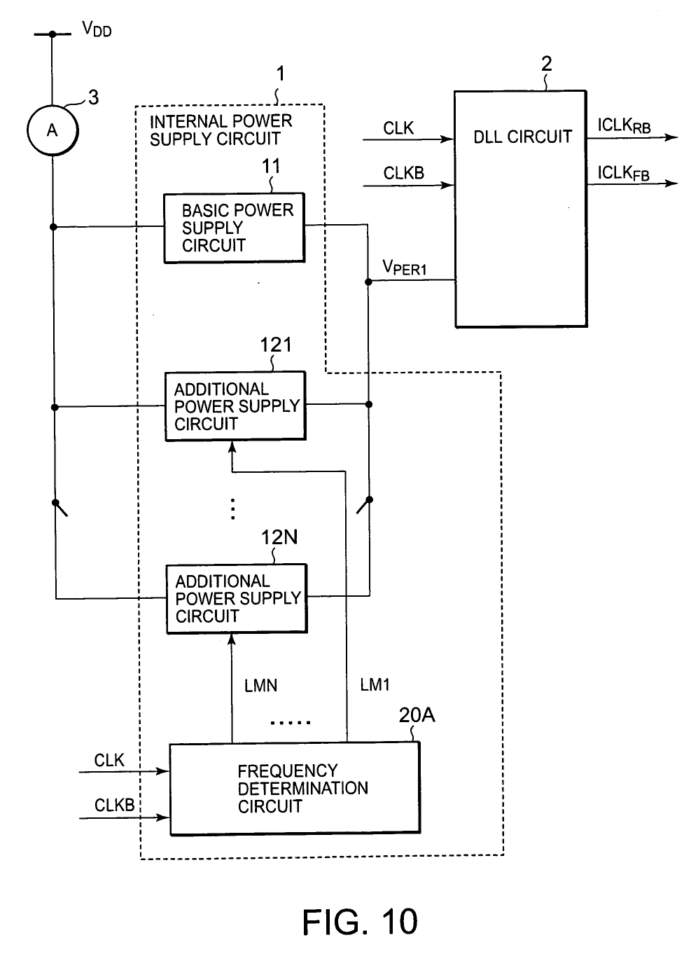

A second embodiment of the present invention will now be described with reference to FIGS. 10 to 13 together.

An internal power supply circuit 1A shown in FIG. 10 has a number N of additional power supply circuits 121 to 12N. A frequency determination circuit 20A controls the connection to each of the N additional power supply circuits 121 to 12N. The other composing elements have the same functions as those described with reference to FIG. 5 and, therefore, the description thereof will be omitted. The basic power supply circuit 11 and the additional power supply circuit 121 to 12N have an identical power supply capacity.

The additional power supply circuits 121 to 12N are essentially the same as the additional power supply circuit 12 described with reference to FIG. 5. Under the control of the frequency determination circuit 20A, each of the additional power supply circuits 121 to 12N is switched on or off to connect or disconnect the external power supply to the internal circuit.

The frequency determination circuit 20A controls the connection of the additional power supply circuits 121 to 12N according to determination signals LM1 to LMN, respectively.

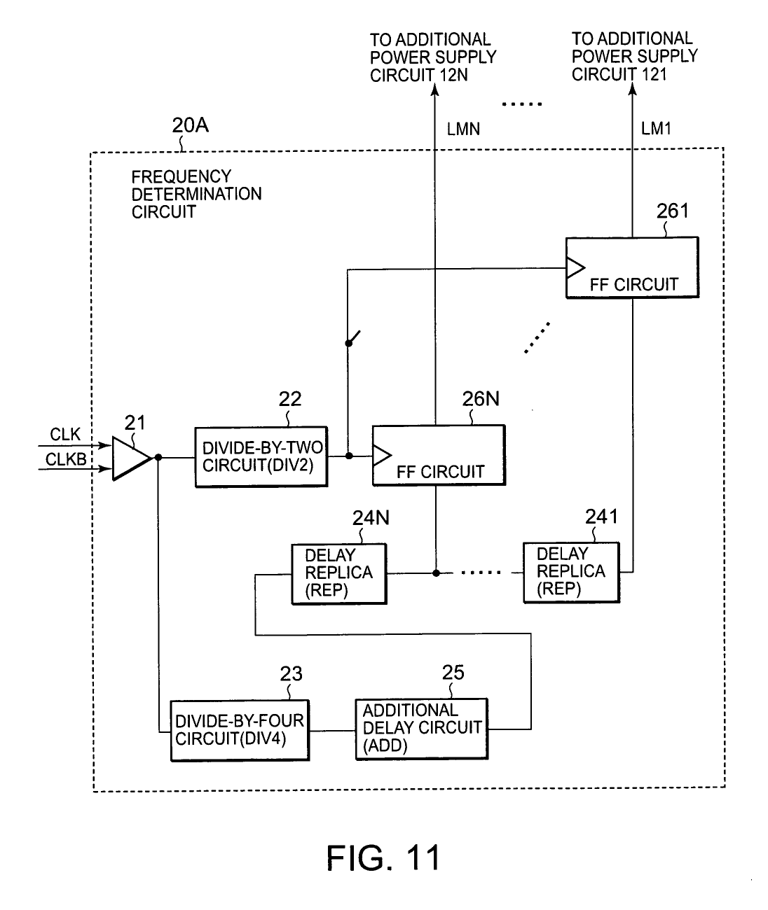

A description will now be made on the frequency determination circuit 20A with reference to FIG. 11.

As shown in FIG. 11, the frequency determination circuit 20A includes a clock buffer 21, a divide-by-two circuit 22, a divide-by-four circuit 23, delay replicas 241 to 24N, an additional delay circuit 25, and flip-flop (FF) circuits 261 to 26N. The composing elements having the same names as those described with reference to FIG. 7 are supposed to have the same functions and structures as those shown in FIG. 7. The delay replicas 241 to 24N have an identical delay time.

The additional delay circuit 25 having an additional delay time t_{ADD} for avoiding the malfunction is arranged upstream of the delay replicas 241 to 24N. A low frequency band is supported by the output from the delay replica 241, while a maximum frequency band is supported by the outputs from all the delay replicas 241 to 24N. A signal output from the divide-by-four circuit 23 is transmitted via the additional delay circuit 25 and propagated through the serial circuit sequentially from the delay replica 24N to the delay replica 241.

Further, the outputs from the delay replicas 241 to 24N are sent to the respective FF circuits 261 to 26N, respectively. When the FF circuits 261 to 26N receive an output from the divide-by-two circuit 22 while receiving the outputs from the delay replicas 241 to 24N, the FF circuits 261 to 26N transmit determination signals LM1 to LMN, respectively.

This means that, when the delay replicas 241 to 24N have an identical delay time t_{REP} as in the present embodiment, the FF circuit 261 outputs a determination signal LM1 corresponding to the delay time t_{REP1}(=N×t_{REP}+t_{ADD}) to the additional power supply circuit 121. In the meantime, the final FF circuit 26N outputs a determination signal LMN corresponding to the delay time t_{REPN}(=t_{REP}+t_{ADD}) to the additional power supply circuit 12N.

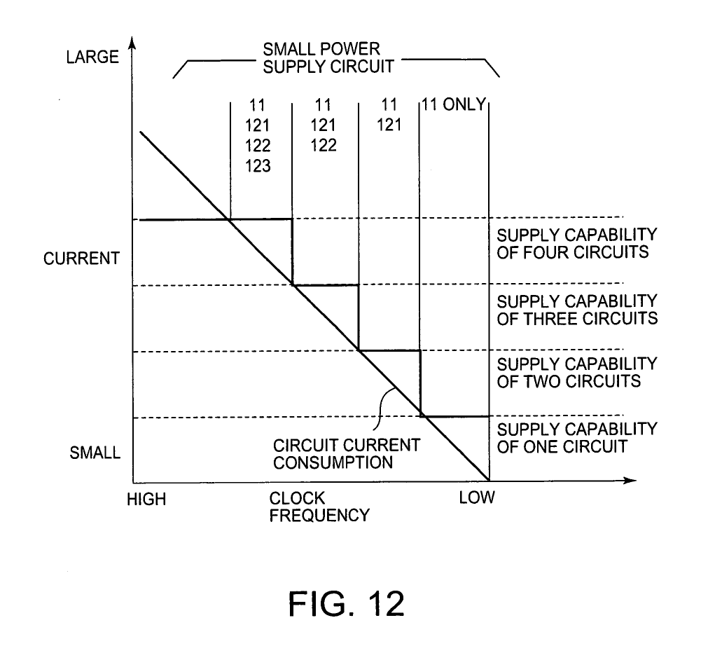

For example, as shown in FIG. 12, when three additional power supply circuits 121 to 123 are provided, all the determination signals LM1 to LMN are “on” if the clock frequency is high. Consequently, all the additional power supply circuits 121 to 123 in addition to the basic power supply circuit 11 are activated to supply power corresponding to four power supply circuits. As the frequency becomes lower, the additional power supply circuits are turned off sequentially from the additional power supply circuit 123 until only the basic power supply circuit 11 is activated when the frequency reaches its minimum.

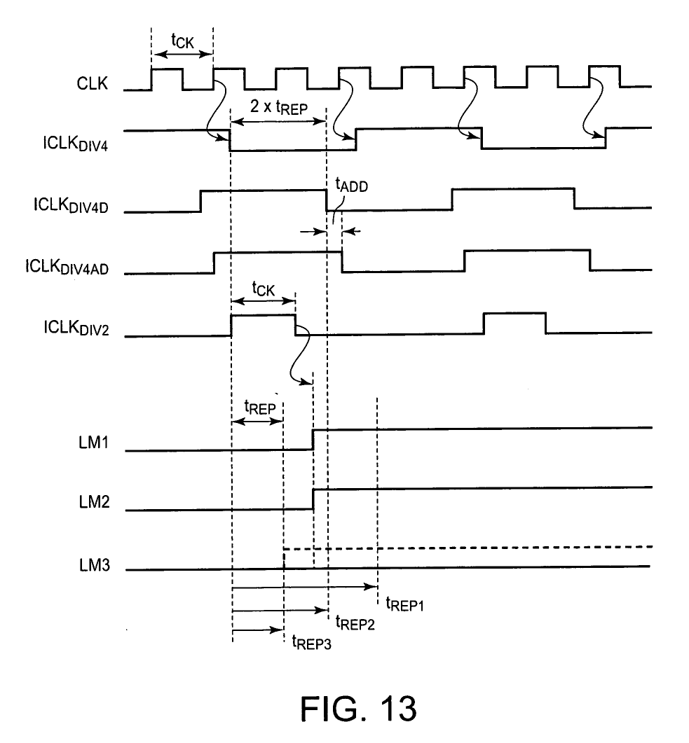

As shown in FIG. 13, and as understood from the above description with reference to FIGS. 8 and 99 when the period t_{CK} of the input clock frequency is greater than t_{REP3}(=t_{REP}+t_{ADD}) and smaller than t_{REP2}(=2×t_{REP}+t_{ADD}), the determination signals LM1 and LM2 become “on”, whereas the determination signal LM3 remains “off”, or is switched to “off” if it is “on”. When the clock frequency is as such, therefore, two additional power supply circuits 121 and 122 are activated to supply power to the electronic circuit in cooperation with the basic power supply circuit 11, while the additional power supply circuit 123 is inactivated to cut off the power supply therefrom.

More specifically, as understood from the description of the embodiment above, delay times t_{REP1} to t_{REPN}, which are mutually different by a time difference of t_{REP}, for example, are assigned to the delay replicas 241 to 24N, respectively. In this case, all the additional power supply circuits 121 to 12N are turn on for the maximum frequency. When the frequency is subsequently decreased at predetermined intervals, the additional power supply circuits 121 to 12N are sequentially switched off one by one.

In the description above, all the additional power supply circuits including the basic power supply circuit are formed in the same size for simplification of the control. As a result, there is provided one additional delay circuit having the additional delay time t_{ADD} for avoiding malfunction, that is, the additional delay circuit 25. However, in order to enable the circuit functions to be properly exhibited, a circuit configuration is also possible, in which one of the delay replicas having different delay times t_{REP1} to t_{REPN} is selected in accordance with the required frequency. Such configuration is rather preferable in some cases. In other words, the present invention is not limited to the specific embodiments as described above.

Such configuration makes it possible to supply current in a most suitable way according to various frequencies used. The configuration is also applicable even in a case in which the relationship between the frequency levels and the current magnitudes is opposite to that described above. According to the present embodiment, therefore, an electronic circuit having characteristics that the current consumption thereof substantially varies depending on the frequency of an externally-input clock can be supplied with current that is optimized precisely. In other words, the useless current consumption can be avoided effectively during operation of the device.

Accordingly to the present invention, the power supply circuit in the internal power supply is divided so that an optimal required number of small power supply circuits is turned on or off by using the determination of the input clock frequency. Therefore, the external power supply and the electronic circuit can be easily connected or disconnected. Thus, the present invention is effectively applicable to electronic circuits having characteristics that the current consumption thereof substantially varies depending on the frequency of an externally-input clock.

What is claimed is:

1. An internal power supply control method for controlling an internal power supply circuit which is externally supplied with power and supplies the power to an electronic circuit, the method comprising the steps of:
dividing the internal power supply circuit into a plurality of small power supply circuits;
detecting the frequency of a clock externally input to the electronic circuit; and
switching the connection and disconnection between the plurality of small power supply circuits and the electronic circuit based on the detected frequency to control the power supply to the electronic circuit.

2. The internal power supply control method according to claim 1, wherein the dividing step divides the plurality of small power supply circuits into one basic power supply circuit and at least one or more additional power supply circuits, the method further comprising the steps of:
normally connecting the external power supply to the electronic circuit by means of the basic power supply circuit; and
connecting the external power supply to the electronic circuit by means of the additional power supply circuit or circuits selected based on the detected frequency.

3. The internal power supply control method according to claim 2, wherein the dividing step divides at least the additional power supply circuits of the power supply circuits so as to have an identical current supply capability.

4. An internal power supply circuit for supplying externally-supplied power to an electronic circuit, comprising:
a plurality of small power supply circuits arranged in parallel;
a frequency determination circuit which samples a clock externally input to the electronic circuit to detect the frequency of the clock, and switches the connection and disconnection between the plurality of small power supply circuits and the electronic circuit based on the detected frequency to control the power supply to the electronic circuit.

5. The internal power supply circuit according to claim 4, wherein the plurality of small power supply circuits include:
one basic power supply circuit for normally connecting the external power supply to the electronic circuit; and
at least one or more additional power supply circuits the power supply of which to the electronic circuit is controlled by the frequency determination circuit.

6. The internal power supply circuit according to claim 5, wherein at least the additional power supply circuits of the plurality of power supply circuits have an identical current supply capability.

7. A semiconductor device comprising an internal power supply circuit as claimed in one of claim 4.

8. A semiconductor storage device formed as an integrated circuit comprising an internal power supply circuit as claimed in one of claim 4, a delay locked loop (DLL) circuit, and a storage circuit.

9. A frequency determination circuit for sampling an externally-input clock to detect the frequency thereof and externally outputting a number N of the detected frequencies as determination signals, the frequency determination circuit comprising:
a clock buffer receiving an externally-input clock;
a divide-by-two circuit receiving the output from the clock buffer to generate a clock with two-times period;
a divide-by-four circuit receiving the output from the clock buffer to generate a clock with four-times period;
an additional delay circuit receiving the output from the divide-by-four circuit and adding a delay time thereto for avoiding a malfunction condition;
an N number of serially connected delay replicas each of which receives the output from the additional delay circuit and delays the received signal by a set time according to a predetermined frequency cycle; and
a flip-flop circuit provided in association with each of the delay replicas, the flip-flop circuit setting an “on” or “off” signal based on the output from the associated delay replica, upon receiving the output from the divide-by-two circuit, and externally outputting the “on” or off” signal thus set as a determination signal.
